(19) United States
(12) Patent Application Publication
(10) Pub. No.: US 2019/0004217 A1
(43) Pub. Date: Jan. 3, 2019

(54) WIDE-ANGLE LENSES AND OPTICAL ASSEMBLIES COMPRISING THE SAME

(71) Applicant: CORNING INCORPORATED, CORNING, NY (US)

(72) Inventors: James Gregory COUILLARD, Ithaca, NY (US); David Francis DAWSON-ELI, Dundee, NY (US); Paul Francis MICHALOSKI, Rochester, NY (US); Leonard Gerard WAMBOLDT, Sunderland, MA (US); William Allen WOOD, Painted Post, NY (US)

(73) Assignee: Corning Incorporated, Corning, NY (US)

(21) Appl. No.: 15/780,871

(22) PCT Filed: Sep. 22, 2016
(86) PCT No.: PCT/US2016/053006

§ 371 Date: Jun. 1, 2018

Related U.S. Application Data
(60) Provisional application No. 62/249,710, filed on Nov. 2, 2015.
(60) Provisional application No. 62/232,850, filed on Sep. 25, 2015.

(51) Int. Cl. G02B 5/00; F21V 5/04; G02B 19/00; H01L 33/58; G02F 1/1335

(52) U.S. Cl. CPC G02B 5/001; F21V 5/04; G02B 19/0009; B82Y 20/00; H01L 33/58; G02F 1/133606; G02B 19/0061

(57) ABSTRACT

Disclosed herein are lenses comprising a first surface, a second convex surface, and a central region disposed therebetween, wherein the central region comprises at least one negative axicon. Also disclosed herein are optical assemblies comprising at least one lens optically coupled to at least one light emitting device.

### CROSS-REFERENCE TO RELATED APPLICATIONS

This application claims the benefit of priority under 35 U.S.C. § 119 of U.S. Provisional Application Ser. No. 62/249,710 filed on Nov. 2, 2015 and U.S. Provisional Application Ser. No. 62/232,850 filed on Sep. 25, 2015, the contents of each of which are relied upon and incorporated herein by reference in their entireties.

### FIELD OF THE DISCLOSURE

The disclosure relates generally to wide-angle lenses, and more particularly to lenses comprising at least one convex surface and at least one negative axicon, as well as display and optical devices comprising such sealed components.

### BACKGROUND

Liquid crystal displays (LCDs) are commonly used in various electronics, such as cell phones, laptops, electronic tablets, televisions, and computer monitors. LCDs typically comprise a blue light emitting diode (LED) and a color converting element, such as a phosphor or quantum dots (QDs). Light emitted from the LED can be converted to longer wavelengths by the color converting element, and this light may then be directed toward the liquid crystal (LC) layer by one or more lenses. Other optical elements can be placed between the lens and the LC layer, such as diffusing, polarizing, and/or filtering layers, to name a few. In some instances, it may be desirable to direct light from the LED at wider angles (e.g., greater than about 65°) to achieve a more diffuse transmission of light. However, current optical assemblies, e.g., assemblies employing a single axicon, may be limited in their ability to refract normally incident light more than about 45° using conventional lens materials.

Accordingly, it would be advantageous to provide lenses capable of refracting light at wide angles, for example, light emanating from an LED or other light emitting structure. It would also be advantageous to provide such wide-angle lenses having a reduced thickness, which may, in turn, reduce the thickness of the overall optical assembly or display device (e.g., LCD stack).

### SUMMARY

The disclosure relates, in various embodiments, to a lens comprising a first surface, a second convex surface, and a central region disposed therebetween, wherein the central region comprises at least one negative axicon. According to various embodiments, the lens may comprise a plurality of negative axicons, such as seven axicons. The at least one negative axicon can, for example, comprise a hollow conical region having a cone half-angle ranging from about 25° to about 40°. The second convex surface may further comprise a conical depression having a cone half-angle ranging from about 80° to about 90°. Suitable materials from which the lens may be constructed include glasses and polymers, such as poly(methyl methacrylate) (PMMA).

Also disclosed herein are optical assemblies comprising at least one lens optically coupled to at least one light emitting device. Such optical assemblies may include, for example, additional components such as a light diffusing layer and/or at least one color converting element. In some embodiments, the at least one light emitting device can be chosen from LEDs. According to additional embodiments, the at least one color converting element may be chosen from quantum dots. In various non-limiting embodiments, the at least one lens may be optically coupled to a sealed device comprising at least one cavity containing at least one quantum dot and at least one light emitting diode. Display devices and luminaires comprising such optical assemblies are also disclosed herein.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and, together with the description, serve to explain the principles and operations of the disclosure.

### BRIEF DESCRIPTION OF THE DRAWINGS

The following detailed description can be further understood when read in conjunction with the following drawings in which, where possible, like numerals are used to refer to like elements, and:

FIG. 1A is a cross-sectional side view of a lens according to various embodiments of the disclosure;

FIG. 1B is an isometric view of a wire frame rendering of a lens according to embodiments of the disclosure;

FIG. 2 is a luminous intensity plot of the lens of FIGS. 1A-B;

FIG. 3A is a cross-sectional side view of a lens according to certain embodiments of the disclosure;

FIG. 3B is a top view of a lens according to various embodiments of the disclosure;

FIG. 3C is an isometric view of a wire frame rendering of a lens according to embodiments of the disclosure;

FIG. 4 is a luminous intensity plot of the lens of FIGS. 3A-C;

FIGS. 5A-D illustrate cross-sectional views of lenses coupled to sealed devices and substrates according to certain embodiments of the disclosure; and

FIGS. 6 and 7 are graphical depictions of optical performance of some embodiments of the disclosure.

### DETAILED DESCRIPTION

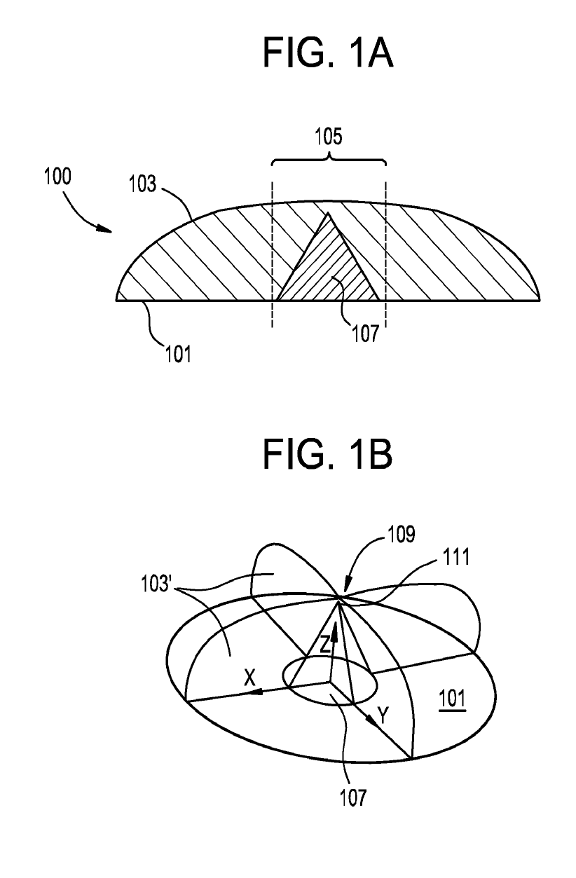

Various embodiments of the disclosure will now be discussed with reference to FIGS. 1-5, which illustrate exemplary lenses and sealed devices. The following general description is intended to provide an overview of the claimed devices, and various aspects will be more specifically discussed throughout the disclosure with reference to the non-limiting embodiments, these embodiments being interchangeable with one another within the context of the disclosure.

Disclosed herein are lenses comprising a first surface, a second convex surface, and a central region disposed therebetween, wherein the central region comprises at least one negative axicon. Also disclosed herein are optical assemblies comprising at least one lens optically coupled to at least one light emitting device.

As used herein, the term “convex” is intended to denote a second surface shape defining a lens that is thinner at its outer edges than at its center, e.g., when the first surface is planar. In some embodiments, the convex second surface may be envisioned as a surface that curves out or extends outward from a centerline or a planar first surface of the lens, e.g., a semi-spherical or semi-ellipsoidal shape. The first and/or second surface of the lens can be envisioned as a rounded dome, the dimensions of which need not be perfectly rounded, semi-spherical, or semi-ellipsoidal. In some embodiments, the convex surface may have one or more planar or substantially planar portions, for example, near the apex and/or central region.

In non-limiting embodiments, a “convex” surface may be rotationally symmetric around a vertical center line of the lens with such shapes as spherical (e.g. as in a typical lens), elliptical, parabolic, or a 2D surface generated by revolving a 1D profile function around the center line. This profile function may be generated by splines and/or may not be continuous in slope. The slope at the center of the surface of the 1D profile may not be zero, so the revolution of the profile function produces a weak or shallow axicon near the central axis. A convex surface that is rotational symmetric around the center line of the lens can also be described by the standard aspheric sag equation, or the Forbes polynomial aspheric sag equation. The sag of the surface that these equations describe is the normal distance from a plane normal to the center line at the surface intersection with that normal line. The sag of a convex surface largely increases in magnitude with distance from the centerline and has a sign that makes the lens thinner at the edge of the lens than the center of the lens. In some radial zones, the lens may become thicker with radial distance from the lens, but is largely thinner at the edge.

It is to be understood that the term “convex” is not limited to surfaces that are rotationally symmetric around the vertical centerline. It is possible that asymmetric surface shape would be beneficial to match possible desired rectangular illumination profiles. The equations that describe this shape might not be standard sag equations, but may describe a free-form surface shape, which is presently increasingly used in the field of optical fabrication. It is also to be understood that the term “convex” is not limited to surfaces that are continuous. The surface may also be a compound surface for which the sag of different spatial regions are defined by different equations.

As used herein, the term “negative axicon” is intended to denote a hollow conical region, which may be envisioned as an indent or depression into the lens substantially in the shape of a cone. According to various embodiments, the vertical centerline of the cone can be spatially oriented to align or substantially align with, or to be parallel or substantially parallel to, the vertical centerline of the second convex surface. The term “negative” is used because the conical surface is part of a negative axiconic lens that diverges collimated light incident on the base of the cone, as opposed to a positive axiconic lens that converges said light to form an axial line focus in space. Just as a spherical surface in optical systems can be designed to be slightly aspherical in shape to improve performance, the shape of the cone can be deviated from a perfect cone to improve performance.

It is to be understood that it may, in certain instance, be difficult to fabricate a negative axicon having a perfectly sharp point. Thus, in some embodiments, the point of the negative axicon may have a conical shape with a point having a blunt or rounded curvature. While a rounded point may increase the amount of light that passes through at shallower angles, e.g., without the desired high angular deviation, it may be possible, in some embodiments, to alter one or more surfaces of the axicon to counteract this effect. For instance, a reflective film may be deposited on the apex of the rounded point of the cone such that light may be reflected backward and can possibly traverse a different path and reflect such that it passes back through the lens at a different point. The rounded apex may also be blocked by coatings or solid objects, such as small balls or spheres affixed or forced into the apex of the cone.

FIG. 1A depicts a cross-sectional side view of a non-limiting embodiment of a lens 100. The lens 100 may comprise a first surface 101 and a second convex surface 103, with a central region 105 disposed therebetweeen. The central region 105 can comprise at least one negative axicon 107. Referring to FIG. 1B, which is a wire frame representation of the lens of FIG. 1A, the second convex surface (envisioned as the surface that would cover intersecting planes 103′) may comprise a shallow conical depression 109, which may correspond to the location where the planes 103′ intersect with or approach the apex 111 of the negative axicon 107.

Referring back to FIG. 1A, while the lens 100 is depicted as plano-convex, e.g., having a first surface 101 that is substantially planar, it is also possible for the first surface to be convex. A convex first surface may, in some instance, provide improved optical properties, such as decreased refraction in the “backwards” (e.g., away from the user) direction. However, for practical purposes, such as ease of construction, a plano-convex lens may be more easily implemented into an optical assembly. In some embodiments, the first surface can be planar or substantially planar or, in other embodiments, the first surface may be convex, e.g., having a radius of curvature ranging from about 100 mm to about 1000 mm. For example, the radius of curvature can range from about 200 mm to about 900 mm, from about 300 mm to about 800 mm, from about 400 mm to about 700 mm, or from about 500 mm to about 600 mm, including all ranges and subranges therebetween. As the first surface becomes more planar, the radius of curvature will increase and ultimately approach infinity.

The first surface 101 may be rotationally symmetric around the vertical centerline of the lens, and may have a spherical or aspheric shape. In additional embodiments, the first surface 101 may be rotationally asymmetric around the vertical centerline of the lens, and may have a free-form shape. Of course, rotationally symmetric or asymmetric shapes can include convex, concave, and planar geometries. Such shapes may include spherical (e.g. as in a typical lens), elliptical, parabolic, compound, or 2D surfaces generated by revolving a 1D profile function around the center line. This profile function may be generated by splines and/or may not be continuous in slope. The slope at the center of the surface of the 1D profile may not be zero, so the revolution of the profile function produces a weak or shallow axicon near the central axis.

As discussed herein, the second convex surface 103 can be envisioned as having a substantially dome-shaped profile, although it is possible that one or more portions of the convex surface can be planar, substantially planar, approaching planar, or even concave, in shape. For example, in the region near the apex and/or the central region 105, the convex surface can comprise a portion that may be relatively planar or concave in shape, e.g., a weak or shallow axicon. The overall radius of curvature of the second convex surface can range, in some embodiments, from about 100 mm to about 1000 mm, such as from about 200 mm to about 900 mm, from about 300 mm to about 800 mm, from about 400 mm to about 700 mm, or from about 500 mm to about 600 mm, including all ranges and subranges therebetween.

As discussed above, the convex second surface 103 may be be rotationally symmetric around the vertical centerline of the lens, and may have a spherical or aspheric shape. In additional embodiments, the convex second surface 103 may be rotationally asymmetric around the vertical centerline of the lens, and may have a free-form shape. Such shapes may include spherical (e.g. as in a typical lens), elliptical, parabolic, compound, or 2D surfaces generated by revolving a 1D profile function around the center line. This profile function may be generated by splines and/or may not be continuous in slope. The slope at the center of the surface of the 1D profile may not be zero, so the revolution of the profile function produces a weak or shallow axicon near the central axis.

Referring back to FIG. 1B, the second convex surface 103 can also comprise a concave, e.g., conical, depression 109 at or near its apex, e.g., proximate to and aligning or substantially aligning with the apex 111 of the negative axicon. This depression can also be referred to as a weak or shallow axicon. Such a depression 109 may have a relatively wide cone half-angle, e.g., approaching flatness, which can range, for example, from about 80° to about 90°, such as from about 82° to about 89°, from about 85° to about 88°, or from about 86° to about 87° (e.g., about 80°, 81°, 82°, 83°, 84°, 85°, 85.5°, 86°, 86.5°, 87°, 87.5°, 88°, 88.5°, 89°, 89.5°, or 90°), including all ranges and subranges therebetween. As used herein, the term “cone half-angle” and variations thereof is intended to denote the angle formed by the sides of the cone with the vertical centerline of the cone. Moreover, such a depression 109 may be relatively shallow, for instance, extending into the lens to a depth of less than about 20% of the lens thickness, such as less than about 15%, less than about 10%, or less than about 5%, e.g., ranging from about 1% to about 20% of the lens thickness, including all ranges and subranges therebetween.

According to various embodiments, the negative axicon 107 may have a cone half-angle ranging from about 25° to about 40°, such as from about 28° to about 35°, or from about 30° to about 32° (e.g., about 25°, 25.5°, 26°, 26.5°, 27°, 27.5°, 28°, 28.5°, 29°, 29.5°, 30°, 30.5°, 31°, 31.5°, 32°, 32.5°, 33°, 33.5°, 34°, 34.5°, 35°, 35.5°, 36°, 37°, 38°, 39°, or 40°), including all ranges and subranges therebetween. A height of the negative axicon can range, in some embodiments, from about 1 mm to about 20 mm, such as from about 2 mm to about 15 mm, from about 3 mm to about 12 mm, from about 4 mm to about 10 mm, or from about 5 mm to about 7 mm, including all ranges and subranges therebetween. Similarly, a diameter of the negative axicon can range from about 1 mm to about 20 mm, such as from about 2 mm to about 15 mm, from about 3 mm to about 12 mm, from about 4 mm to about 10 mm, or from about 5 mm to about 8 mm, including all ranges and subranges therebetween. In additional embodiments, the height of the negative axicon may be chosen relative to the diameter, e.g., in a ratio of height:diameter ranging from about 0.5:1 to about 2:1, such as from about 0.75:1 to about 1.5:1, or from about 1:1 to about 1.2:1, including all ranges and subranges therebetween.

In non-limiting embodiments, the height and/or diameter of the negative axicon 107 may depend on the size of the light emitting device to be optically coupled to the lens 100. For instance, the diameter of the negative axicon may be chosen to be larger than a dimension of the light emitting device (e.g., diameter, length, and/or width). In some embodiments, the diameter of the negative axicon may be at least about 10% greater than the greatest linear dimension of the light emitting device, such as greater than about 20%, greater than about 30%, greater than about 40%, greater than about 50%, or more, e.g., ranging from about 10% to about 50%, including all ranges and subranges therebetween. In additional embodiments, the height of the negative axicon may be chosen to be larger than the greatest linear dimension of the light emitting device, for example, at least about 40% greater, about 45% greater, about 50% greater, about 55% greater, about 60% greater, or more, e.g., ranging from about 40% to about 60% greater, including all ranges and subranges therebetween.

The overall height (or thickness) of the lens 100 may also be dependent, e.g., on the height of the negative axicon 107. For instance, the lens height (or thickness) may be at least about 5% greater than the axicon height, such as greater than 10%, greater than 15%, greater than 20%, or greater than 25%, e.g., ranging from about 5% to about 25%, including all ranges and subranges therebetween. The overall height (or thickness) of the lens can thus range, in non-limiting embodiments, from about 1 mm to about 20 mm, from about 2 mm to about 15 mm, from about 3 to about 12 mm, from about 4 mm to about 10 mm, or from about 5 mm to about 7 mm, including all ranges and subranges therebetween. Similarly, a diameter of the lens can range, for example, from about 1 mm to about 100 mm, from about 5 mm to about 90 mm, from about 10 mm to about 80 mm, from about 20 mm to about 70 mm, from about 30 mm to about 60 mm, or from about 40 mm to about 50 mm, including all ranges and subranges therebetween.

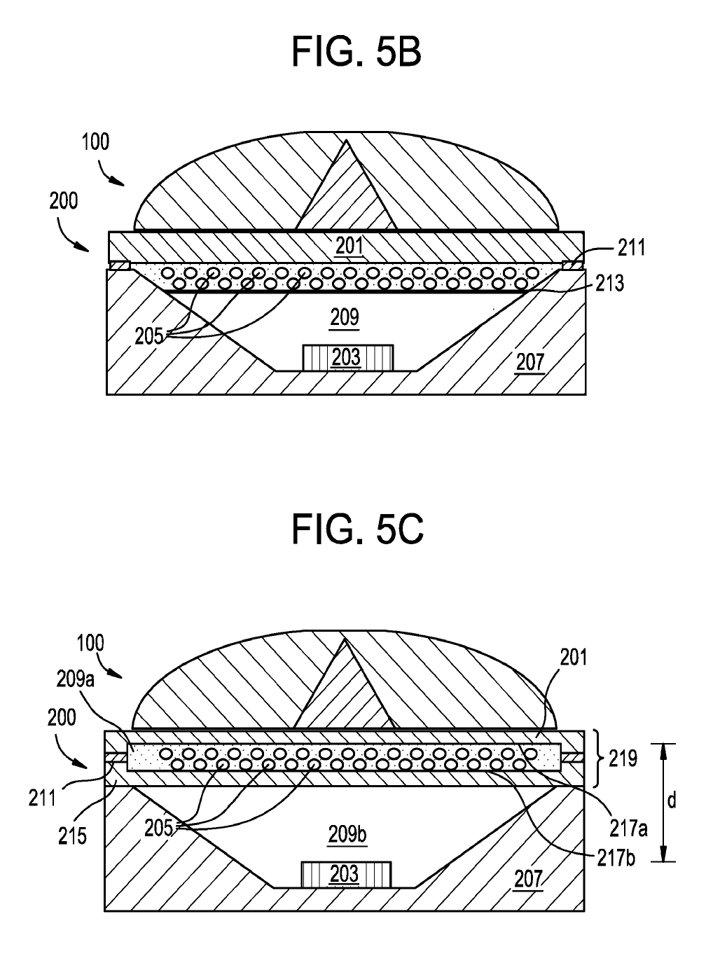

Without wishing to be bound by theory, and as discussed in more detail with respect to FIG. 5D, it is believed that the negative axicon by itself may not refract normally incident light more than about 45° using conventional lens materials. However, the surrounding convex lens can provide an additional total internal reflection (TIR), which may bound at least a portion of the rays exiting the axicon and direct them outward at larger angles. TIR occurs when light propagates from a higher index medium to a lower index medium (e.g. air) and the angle of incidence is higher than the critical angle. The critical angle for light traveling from the central region into air is the arc-sine of the reciprocal of the index of the central region.

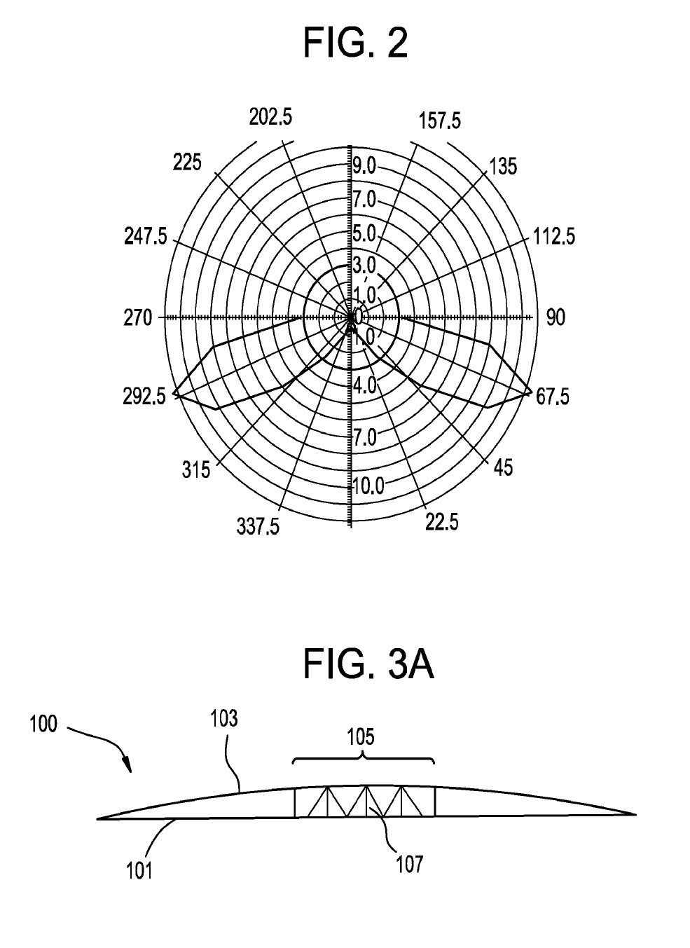

FIG. 2 is an exemplary far-field intensity plot of an exemplary lens generally configured as depicted in FIGS. 1A-B as illuminated by a Lambertian emitter (lens material: PMMA, lens diameter: 54 mm, lens height: 14.5 mm, axicon cone half-angle: 26.8°, axicon diameter: 15.6 mm, depression cone half-angle: 85.2°). As can be seen in the plot, the emission peak is around 68° (with a corresponding peak in the opposite direction around 292°), and the refracted light spans angles in a region ranging from about 30° up to nearly 90° (or from about 330° to about 270°). Of course, the depicted plot is exemplary only and it is to be understood that the lens materials and dimensions can be varied to produce different emission peaks and emission regions, without limitation.

This plot depicted in FIG. 2 assumes that the lens will sit atop a non-reflective substrate (e.g., a flat substrate painted black), thus, no radiation is illustrated in the region from 90° to 270° (i.e., the region indicating backward refraction). In some embodiments, there may be a small amount of radiation in this region. According to non-limiting embodiments, the lenses disclosed herein may refract light from a light emitting device to an angle of at least about 65°, such as at least about 70°, at least about 75°, at least about 80°, at least about 85°, or higher, (e.g., about 65°, 66°, 67°, 68°, 69°, 70°, 71°, 72°, 73°, 74°, 75°, 76°, 77°, 78°, 79°, 80°, 81°, 82°, 83°, 84°, 85°, 86°, 87°, 88°, or 89°), including all ranges and subranges therebetween.

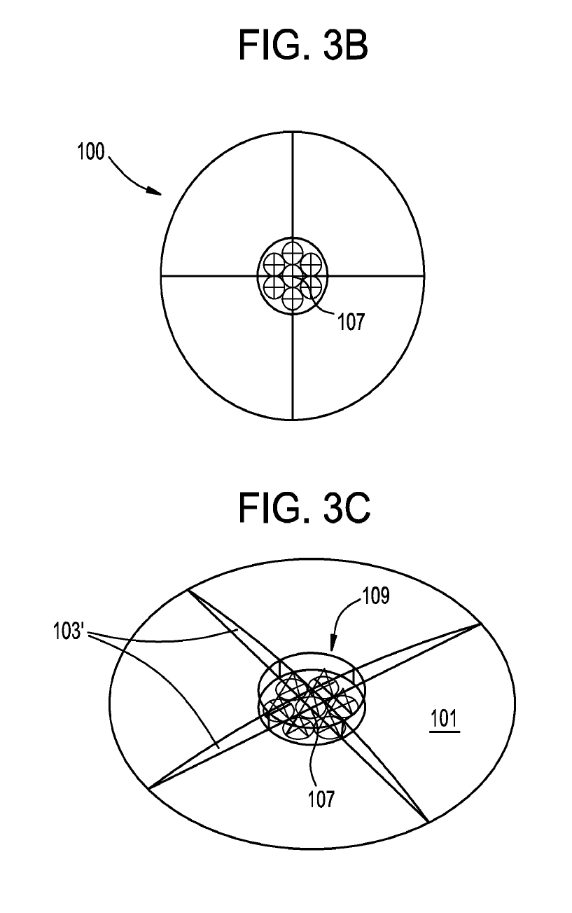

While FIGS. 1A-B illustrate a lens 100 comprising a single negative axicon 107, it is also possible for the lens to comprise more than one negative axicon, e.g., as depicted in FIGS. 3A-C. As depicted in FIG. 3A, which is a cross-sectional side view of an exemplary lens 100, the lens can comprise a first surface 101, a second convex surface 103, and a central region 105 disposed therebetween. The central region 105 can comprise at least one negative axicon 107. As depicted in the non-limiting cross-sectional view of FIG. 3A, only three axicons 107 are visible. However, in the top view illustrated in FIG. 3B, and in the isometric view illustrated in FIG. 3C, all seven axicons 107 are visible.

Of course, the depicted embodiment is not intended to be limiting and it is to be understood that the lens can comprise any number of negative axicons. For example, the lens may comprise one negative axicon or more than one, such as two, three, four, five, six, seven, eight, nine, ten, or more axicons, as desired. Moreover, the plurality of negative axicons may be arranged in any manner, which can be ordered or random, symmetrical or asymmetrical. For instance, an annular arrangement about a central axicon, e.g., as depicted in FIGS. 3B-C, can be used or any other geometrical arrangement, such as a linear array, a triangular array, a hexagonal array, or any other polygonal shape, to name a few. Additionally, while FIGS. 3B-C illustrate negative axicons having substantially the same shape and size, it is possible to have one or more axicons having a different shape and/or size than the remaining axicons in the array, e.g., a larger central axicon surrounded by smaller peripheral axicons, and so on. Finally, while FIGS. 3B-C depict non-intersecting or non-overlapping negative axicons, e.g., with space around the bases of each axicon, it is also possible for the axicons to overlap in the array. For example, the negative axicons depicted in FIGS. 3A-B could be drawn in to create a tighter, more hexagonal array, rather than the circular array of packed, discrete negative axicons depicted.

With particular reference to FIG. 3C, and similar to the embodiment depicted in FIG. 1B, the second convex surface (graphically represented as the surface that would cover intersecting planes 103′) may also comprise a shallow conical depression 109, which may correspond to the location where the planes 103′ intersect with or approach the central region 105 (e.g., apex) of the lens 100. Such a depression 109 may have a relatively wide cone half-angle, e.g., approaching flatness, which can range, for example, from about 80° to about 90°, such as from about 82° to about 89°, from about 85° to about 88°, or from about 86° to about 87° (e.g., about 80°, 81°, 82°, 83°, 84°, 85°, 85.5°, 86°, 86.5°, 87°, 87.5°, 88°, 88.5°, 89°, 89.5°, or 90°), including all ranges and subranges therebetween. Moreover, such a depression 109 may be relatively shallow, for instance, extending into the lens to a depth of less than about 20% of the lens thickness, such as less than about 15%, less than about 10%, or less than about 5%, e.g., ranging from about 1% to about 20% of the lens thickness, including all ranges and subranges therebetween.

Referring back to FIG. 3A, while the lens 100 is depicted as plano-convex, e.g., having a first surface 101 that is substantially planar, it is also possible for the first surface to be convex. In some embodiments, the first surface can be planar or substantially planar or, in other embodiments, the first surface may be convex, e.g., having a radius of curvature ranging from about 100 mm to about 1000 mm. For example, the radius of curvature can range from about 200 mm to about 900 mm, from about 300 mm to about 800 mm, from about 400 mm to about 700 mm, or from about 500 mm to about 600 mm, including all ranges and subranges therebetween.

The first surface 101 may be rotationally symmetric around the vertical centerline of the lens, and may have a spherical or aspheric shape. In additional embodiments, the first surface 101 may be rotationally asymmetric around the vertical centerline of the lens, and may have a free-form shape. Of course, rotationally symmetric or asymmetric shapes can include convex, concave, and planar geometries. Such shapes may include spherical (e.g. as in a typical lens), elliptical, parabolic, or 2D surfaces generated by revolving a 1D profile function around the center line. This profile function may be generated by splines and/or may not be continuous in slope. The slope at the center of the surface of the 1D profile may not be zero, so the revolution of the profile function produces a weak or shallow axicon near the central axis.

As discussed above with reference to FIG. 1A above, the second convex surface 103 can be envisioned as having a substantially dome-shaped profile (as depicted in FIG. 3A), although it is possible that one or more portions of the convex surface can be planar, substantially planar, approaching planar, or even convex, in shape. For example, in the region near the apex, e.g., the central region 105, the convex surface can comprise a portion that may be relatively planar or convex in shape, e.g., a weak or shallow axicon. The overall radius of curvature of the second convex surface can range, in some embodiments, from about 100 mm to about 1000 mm, such as from about 200 mm to about 900 mm, from about 300 mm to about 800 mm, from about 400 mm to about 700 mm, or from about 500 mm to about 600 mm, including all ranges and subranges therebetween.

According to various embodiments, each negative axicon 107 in the plurality of axicons may have a cone half-angle ranging from about 25° to about 40°, such as from about 28° to about 35°, or from about 30° to about 32° (e.g., about 25°, 25.5°, 26°, 26.5°, 27°, 27.5°, 28°, 28.5°, 29°, 29.5°, 30°, 30.5°, 31°, 31.5°, 32°, 32.5°, 33°, 33.5°, 34°, 34.5°, 35°, 35.5°, 36°, 37°, 38°, 39°, or 40°) including all ranges and subranges therebetween. A height of each negative axicon can range, in some embodiments, from about 0.5 mm to about 10 mm, such as from about 1 mm to about 8 mm, from about 2 mm to about 7 mm, from about 3 mm to about 6 mm, or from about 4 mm to about 5 mm, including all ranges and subranges therebetween. Similarly, a diameter of the negative axicon can range from about 0.5 mm to about 10 mm, such as from about 1 mm to about 8 mm, from about 2 mm to about 7 mm, from about 3 mm to about 6 mm, or from about 4 mm to about 5 mm, including all ranges and subranges therebetween.

In non-limiting embodiments, the height and/or diameter of each negative axicon 107 in the plurality of axicons may depend on the size of the light emitting device to be optically coupled to the lens 100. For instance, the diameter of each negative axicon may be chosen such that, collectively, they have a surface area larger than the surface area of the light emitting device, e.g., their collective diameters may be greater than a dimension of the light emitting device (e.g., diameter, length, and/or width). In some embodiments, the collective surface area of the plurality of negative axicons may be at least about 10% greater than the surface area of the light emitting device, such as greater than about 20%, greater than about 30%, greater than about 40%, greater than about 50%, or more, e.g., ranging from about 10% to about 50%, including all ranges and subranges therebetween. In additional embodiments, the height of each negative axicon may be chosen relative to the diameter, e.g., in a ratio of height:diameter ranging from about 0.5:1 to about 2:1, such as from about 0.75:1 to about 1.5:1, or from about 1:1 to about 1.2:1, including all ranges and subranges therebetween.

The overall height (or thickness) of the lens 100 may also be dependent, e.g., on the height of the negative axicon 107. For instance, the lens height (or thickness) may be at least about 5% greater than the axicon height, such as greater than 10%, greater than 15%, greater than 20%, or greater than 25%, e.g., ranging from about 5% to about 25%, including all ranges and subranges therebetween. The overall height (or thickness) of the lens can thus range, in non-limiting embodiments, from about 1 mm to about 20 mm, from about 2 mm to about 15 mm, from about 3 mm to about 12 mm, from about 4 mm to about 10 mm, or from about 5 mm to about 7 mm, including all ranges and subranges therebetween. Similarly, a diameter of the lens can range, for example, from about 1 mm to about 100 mm, from about 5 mm to about 90 mm, from about 10 mm to about 80 mm, from about 20 mm to about 70 mm, from about 30 mm to about 60 mm, or from about 40 mm to about 50 mm, including all ranges and subranges therebetween.

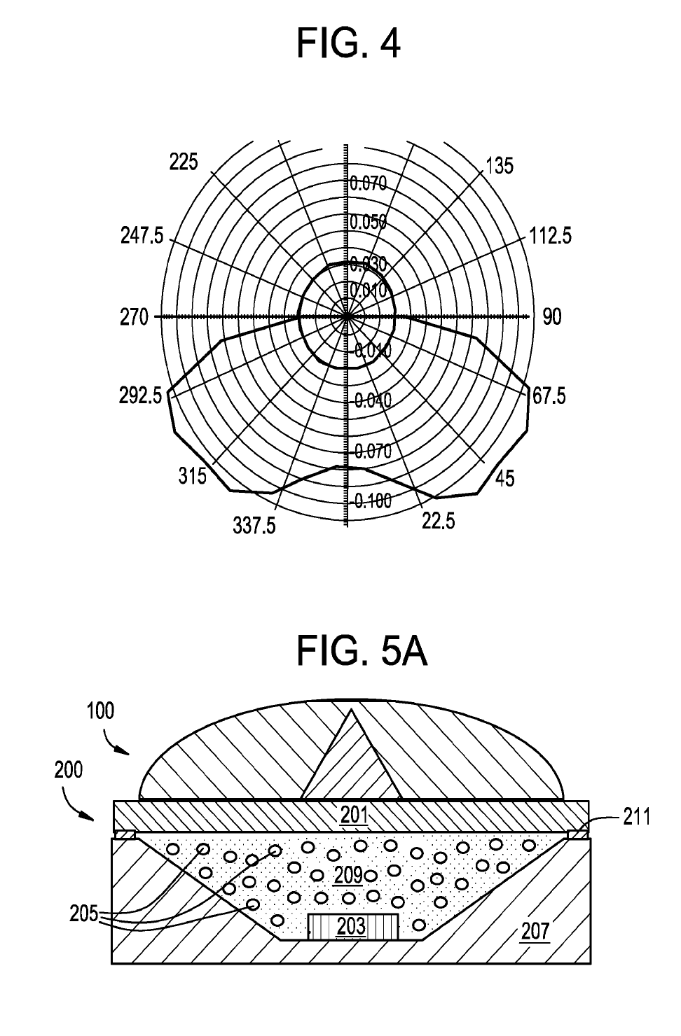

FIG. 4 is an exemplary far-field intensity plot of an exemplary lens generally configured as depicted in FIGS. 3A-C as illuminated by a Lambertian emitter (lens material: PMMA, lens diameter: 54 mm, lens height: 2.9 mm, axicon cone half-angle: 35.5°, axicon diameter: 4.07 mm, depression cone half-angle: 88.8°). As can be seen in the plot, the lens refracts light at angles above about 65°, but also refracts a significant amount of light at smaller angles. Of course, the depicted plot is exemplary only and it is to be understood that the lens materials and dimensions can be varied to produce different emission peaks and emission regions, without limitation.

Without wishing to be bound by theory, it is believed and has been discovered that incorporating one or more negative axicons into the lens can produce a thinner lens (e.g., lower height value), because each axicon in the array of axicons need only cover a portion of the emitter area and can thus have a correspondingly smaller diameter (and height). However, the thinness of the lens should be balanced against the amount of light refraction at smaller angles (e.g., less than about 65°), depending on the particular application and desired result. Further, it has been discovered that exemplary lenses according to embodiments herein may allow for a smaller emitter. For example, when coupled to a sealed device, e.g., as shown in FIGS. 5A-D, the LED size and/or amount of color converting element may be reduced due to the increased distribution of light achieved by the lenses disclosed herein. This may be advantageous in terms of decreasing the overall size of the device incorporating such an optical assembly, providing flexibility as to the physical location of the optical assembly within the device, and/or decreasing the amount of color converting element needed to obtain a desired transmission and/or distribution of light and, thus, decreasing the corresponding expense and/or hazard associated with such materials.

The lenses disclosed herein can be incorporated into optical assemblies according to various non-limiting embodiments. For example, an optical assembly can comprise at least one lens optically coupled to at least one light emitting device. As used herein, the term “optically coupled” is intended to denote that a light emitting device is positioned relative to, e.g., in proximity to, the lens such that light is introduced into the lens. When normally incident light is injected into the lens, according to certain embodiments, the light may become trapped and bounce within the lens due to total internal reflection (TIR), eventually exiting the lens at a refracted angle.

According to various embodiments, the at least one lens may be optically coupled to the light emitting device by physical contact and/or proximity. For instance, the lens may be in physical contact with a substrate on which or in which the light emitting device is placed (see, e.g., FIGS. 5A-D). In some embodiments, the light emitting device may be placed at a distance from the lens, the distance ranging, for example, from about 0.1 mm to about 5 mm, such as from about 0.25 mm to about 4 mm, from about 0.5 mm to about 3 mm, from about 0.75 mm to about 2 mm, from about 1 mm to about 1.75 mm, or from about 1.25 mm to about 1.5 mm, including all ranges and subranges therebetween.

In some embodiments, the at least one light emitting device can be chosen from LEDs, organic LEDs (OLEDs), laser diodes (LDs), and the like. Optical assemblies as disclosed herein may also include, for example, additional components such as a light diffusing layer and/or at least one color converting element. According to additional embodiments, the at least one color converting element may be chosen from phosphors and quantum dots. In further non-limiting embodiments, the at least one lens may be optically coupled to a sealed device comprising at least one cavity containing at least one quantum dot and at least one LED. Exemplary sealed devices are disclosed, for instance, in co-pending U.S. Provisional Application No. 62/204,122, filed on Aug. 12, 2015 and U.S. Provisional Application No. 62/214,548, filed on Sep. 4, 2015, which are each incorporated herein by reference. Display devices and luminaires comprising such optical assemblies are also disclosed herein

Several non-limiting examples are provided in FIGS. 5A-D, which illustrate cross-sectional views of lenses 100 optically coupled to various sealed devices 200. Referring to FIGS. 5A-B, the sealed devices 200 can comprise a first substrate 201 and a second substrate 207 comprising at least one cavity 209. The at least one cavity 209 can contain at least one quantum dot 205. The at least one cavity 209 can also contain at least one LED component 203. The first substrate 207 and second substrate 201 can be joined together by at least one seal 211, which can extend around the at least one cavity 209. Alternatively, the seal can extend around more than one cavity, such as a group of two or more cavities (not shown).

The LED 203 may have any dimension (e.g., diameter, length, and/or width), for example, from about 100 μm to about 1 mm, from about 200 μm to about 900 μm, from about 300 μm to about 800 μm, from about 400 μm to about 700 μm, from about 350 μm to about 400 μm, including all ranges and subranges therebetween. In additional embodiments, the LED 203 can have at least one dimension (e.g., diameter, length, and/or width) greater than about 1 mm, such as ranging from about 1 mm to about 30 mm, from about 2 mm to about 25 mm, from about 3 mm to about 20 mm, from about 4 mm to about 15 mm, or from about 5 mm to about 10 mm, including all ranges and subranges therebetween. The LED 203 may also provide a high or low flux, for example, for high flux purposes the LED 203 may emit 20 W/cm² or more. For low flux purposes, the LED 203 may emit less than 20 W/cm².

In the non-limiting embodiment depicted in FIG. 5A, the at least one LED component 203 can be in direct contact with the at least one quantum dot 205. As used herein the term “contact” is intended to denote direct physical contact or interaction between two listed elements, e.g., the quantum dot and LED component are able to physically interact with one another within the cavity. In the non-limiting embodiment depicted in FIG. 5B, the at least one LED component 203 and the at least one quantum dot 205 may be present in the same cavity, but are separated, e.g., by a separation barrier or film 213.

In the non-limiting embodiment depicted in FIG. 5C, a sealed device 200 may include at least one LED component 203, a first substrate 201, a second substrate 207, and a third substrate 215. The first substrate 201 and third substrate 215 may form a hermetically sealed package or device 219 which forms an enclosed and encapsulated region 209a containing the at least one quantum dot 205. In some embodiments the hermetically sealed package or device 219 will also include one or more films 217a, b such as, but not limited to, films that act as high pass filters and films that act as low pass filters or films that are provided to filter predetermined wavelengths of light.

In some embodiments, the at least one LED component 203 can be placed in cavity 209b and spaced apart from the at least one quantum dot 205 by a predetermined distance “d”. In some embodiments the predetermined distance can be less than or equal to about 100 μm. In other embodiments, the predetermined distance is between about 50 μm and about 2 mm, between about 75 μm and about 500 μm, between about 90 μm and about 300 μm, and all subranges therebetween. In some embodiments, the predetermined distance is measured from a top surface of the LED component 203 to a midline of the enclosed and encapsulated region containing the at least one quantum dot 205. Of course, the predetermined distance may also be measured to any portion of the enclosed and encapsulated region containing the at least one quantum dot 205 such as but not limited to an upper surface of the third substrate 215 facing the at least one quantum dot 205, a lower surface of the first substrate 201 facing the at least one quantum dot 205, or a surface formed by any one of the films or filters 217a, b which may be present in the hermetically sealed package or device 219.

In some embodiments, exemplary films include a filter 217a which prevents blue light from an exemplary LED component 203 from escaping the device 219 in one direction and/or another filter 217b which prevents red light (or another light emitted by excited quantum dot material) from escaping the device 219 in a second direction. For example, in some embodiments, the device 200 may comprise one or more LED components 203 contained in a well or other enclosure formed by the second substrate 207 and/or other substrates. A hermetically sealed package or device 219 in close proximity (e.g., a predetermined distance as discussed above) to the one or more LED components may be fixed to or sealed to the second substrate 207 and may comprise a first substrate 201 hermetically sealed to a third substrate 215 which forms an encapsulated region containing single wavelength quantum dot material 205 configured to emit light in an infrared wavelength, near-infrared wavelength, or in a predetermined spectrum (e.g., red) when excited by light emitted from the one or more LED components 203.

The quantum dot material 205 can be spaced apart from the LED component 203 by a predetermined distance. In such an exemplary embodiment, a first filter 217a may be provided on the bottom (or top) surface of the first substrate 201 to filter blue light from emitting though the top surface of the device 200 and a second filter 217b may be provided on the top (or bottom) surface of the third substrate 215 to filter excited light from the quantum dot material from exiting the bottom surface of the third substrate 215.

FIG. 5D depicts a lens 100 optically coupled to a sealed device 200 including at least one LED component 203, a first substrate 201, a second substrate 207, and a third substrate 215. The first substrate 201 and third substrate 215 may be connected by a seal 211 to form a hermetically sealed package or device 219 which forms an enclosed and encapsulated region 209a containing the at least one quantum dot 205. In some embodiments the hermetically sealed package or device 219 will also include one or more films 217c such as, but not limited to, reflective films that act to redirect light such that it passes only through the encapsulated region 209a comprising the color converting element. While film 217c is depicted on an exterior surface of substrate 215, such a film can be placed anywhere on the device 219, e.g., any suitable interior or exterior surface, e.g., between substrates 201 and 215. The interior or exterior surfaces of the second substrate 207 may likewise be provided with such a reflective film if desired and/or necessary to prevent light leakage from the device. It should be noted that while the at least one quantum dot 205 or QD material is depicted as substantially centered or over the LED component 203, the claims appended herewith should not be so limited as it is envisioned that such embodiments can include the at least one quantum dot 205 or QD material to extend along or over the entirety of the encapsulated region 209b as depicted in FIG. 5C.

As noted above, in some embodiments, the filter 217c may be provided on the bottom surface of the substrate 215 to filter blue light. These filters 217a, 217b, 217c, alone or in combination can in some embodiments include a plurality of thin film layers selected for their optical properties. In particular exemplary filters 217a, 217b, 217c can be designed to have high transmission for blue wavelengths to allow a blue LED light to emerge from a light guide plate adjacent the device 200. Such filters can also possess a high reflection for red and green wavelengths to reduce backreflection of light from the quantum dot material 205 back into the light guide plate.

One exemplary low pass filter 217a, 217b, 217c, includes a thin film stack made from multiple layers of high refractive index and low refractive index materials. In some embodiments, the stack includes an odd number of layers; in other embodiments, the stack includes an even number of layers. In some embodiments, the plural layers include 2 or more layers, 3 or more layers, 4 or more layers, 5 or more layers, 6 or more layers, 7 or more layers, 8 or more layers, 9 or more layers, 10 or more layers, 11 or more layers, 12 or more layers, 13 or more layers, 14 or more layers, 15 or more layers, 16 or more layers, 17 or more layers, 18 or more layers, 19 or more layers, 20 or more layers, 21 or more layers, 22 or more layers, 23 or more layers, 24 or more layers, 25 or more layers, 26 or more layers, 27 or more layers, 28 or more layers, 29 or more layers, and so on. In one embodiment, an exemplary filter comprises multiple alternating layers of a suitable high refractive index material and a suitable low refractive index material. Exemplary high refractive index materials include, but are not limited to, Nb₂O₅, Ta₂O₅, TiO₂, and compound oxides thereof. Exemplary low refractive index materials include, but are not limited to, SiO₂, ZrO₂, HfO₂, Bi₂O₃, La₂O₃, Al₂O₃, and compound oxides thereof. In one embodiment, an exemplary filter includes alternating layers of Nb₂O₅ and SiO₂ to a total thickness of approximately 1.8 μm which can be designed to pass light at 450 nm while reflecting 550 nm and 632 nm as provided in Table 1 below.

TABLE 1

| Layer | Material | Thickness (nm) |
|---|---|---|
| 21 | Nb₂O₅ | 80.19 |
| 20 | SiO₂ | 105.22 |
| 19 | Nb₂O₅ | 66.82 |
| 18 | SiO₂ | 105.22 |
| 17 | Nb₂O₅ | 66.82 |
| 16 | SiO₂ | 105.22 |
| 15 | Nb₂O₅ | 66.82 |
| 14 | SiO₂ | 105.22 |
| 13 | Nb₂O₅ | 66.82 |
| 12 | SiO₂ | 105.22 |
| 11 | Nb₂O₅ | 66.82 |
| 10 | SiO₂ | 105.22 |
| 9 | Nb₂O₅ | 66.82 |
| 8 | SiO₂ | 105.22 |
| 7 | Nb₂O₅ | 66.82 |
| 6 | SiO₂ | 105.22 |
| 5 | Nb₂O₅ | 66.82 |
| 4 | SiO₂ | 105.22 |
| 3 | Nb₂O₅ | 66.82 |
| 2 | SiO₂ | 105.22 |
| 1 | Nb₂O₅ | 80.19 |
| 0 | Glass | — |

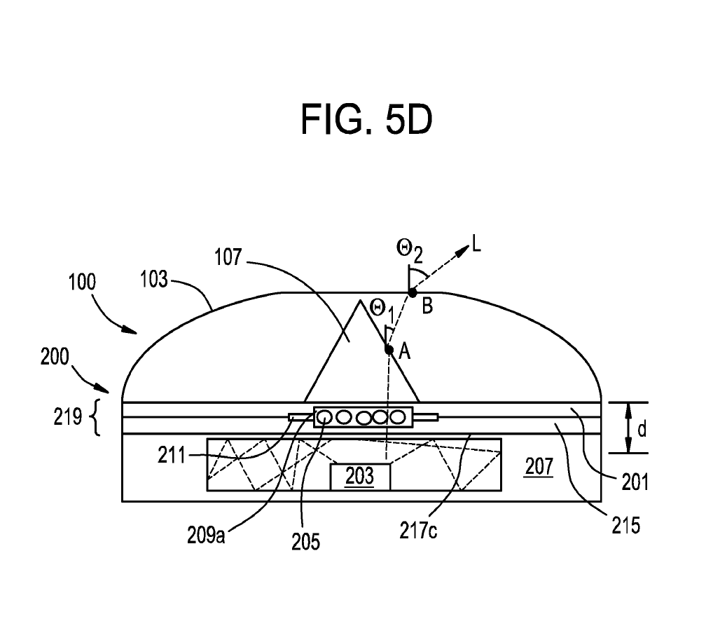

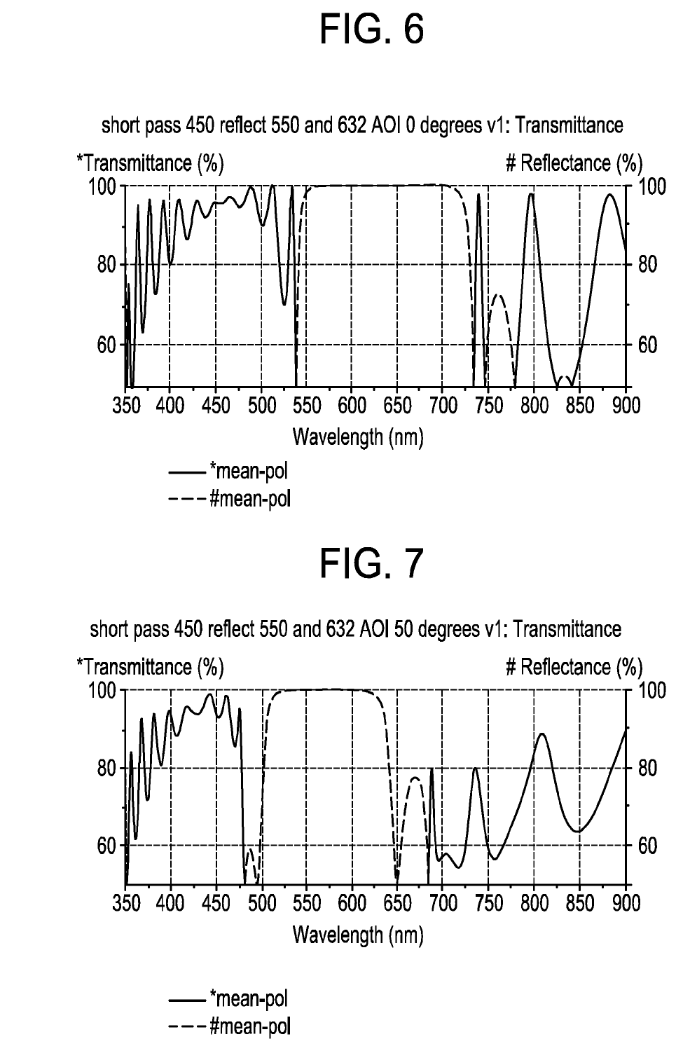

FIGS. 6 and 7 are graphical depictions of optical performance of some embodiments of the disclosure. With reference to FIG. 6, an optical performance of the filter from Table 1 at normal incidence is provided. It should be noted that the depicted embodiment provides a high transmission (solid line) at 450 nm and near 100% reflection (dashed line) over 550˜640 nm. With reference to FIG. 7, an optical performance of the filter from Table 1 at 50° incidence is provided. It should be noted that the depicted embodiment provides a transmission of blue light and reflection of red and green light even at high angles.

Exemplary filter embodiments can be used between a side lit or direct lit light guide plates and adjacent QD material, i.e., intermediate the QD material and light guide plates or as described above with reference to FIGS. 2B and 2C. For example, with continued reference to FIG. 2C, an exemplary filter 217c can improve the efficiency of directing light out of the package. In other embodiments, another location for the low pass filter can be on the cover glass (e.g., third substrate 215) such that the UV absorbing material is also the interference filter. Specifically, the material used as a high index material absorbs sufficient UV to enable the laser welding process described herein. These exemplary layers of material can be deposited by any number of thin film methods known in the art such as sputtering, plasma-enhanced chemical vapor deposition, and the like. The film or layer may be deposited directly onto the light guide plate or substrate or as a separate layer which is then attached by an optically clear adhesive. It was discovered that embodiments described herein having such filters (1) resulted in a higher forward light output, increasing overall brightness of the device 200 or light guide plate, (2) improved quantum dot conversion efficiency, enabling use of less quantum dot material, and (3) could rely on conventional thin film processing technology for ease of manufacture.

The negative axicon 107 can be substantially aligned with the LED 203 such that light L emanating from the LED (indicated by dashed lines) enters into the hollow center of the lens 100. The light L may be refracted by an internal surface of the negative axicon 107, e.g., at point A. At this point the light may be refracted at an initial angle Θ₁ which may, in some embodiments, be less than about 45°, such as less than about 40°, less than about 35°, less than about 30°, less than about 25°, less than about 20°, less than about 15°, less than about 10°, or less than about 5°, e.g., ranging from about 5° to about 45°, including all ranges and subranges therebetween. The light L may then further refracted by the convex surface 103, e.g., at point B. The light L thus refracted may have an angle Θ₂ which may, in some embodiments, be greater than about 65°, such as greater than about 70°, greater than about 75°, greater than about 80°, or greater than about 85°, e.g., ranging from about 65° to about 90°, including all ranges and subranges therebetween.

The first substrate 201, second substrate 207 and/or third substrate 215 can, in some embodiments, be chosen from glass substrates and may comprise any glass known in the art for use in display and other electronic devices. Suitable glasses can include, but are not limited to, aluminosilicate, alkali-aluminosilicate, borosilicate, alkali-borosilicate, aluminoborosilicate, alkali-aluminoborosilicate, and other suitable glasses. These substrates may, in various embodiments, be chemically strengthened and/or thermally tempered. Non-limiting examples of suitable commercially available substrates include EAGLE XG®, Lotus™, Iris™, Willow®, and Gorilla® glasses from Corning Incorporated, to name a few. Glasses that have been chemically strengthened by ion exchange may be suitable as substrates according to some non-limiting embodiments. In non-limiting embodiments, the lens 100 may also be constructed from a glass material as set forth above.

According to various embodiments, the first, second, and/or third glass substrates 201, 207, 215 may have a compressive stress greater than about 100 MPa and a depth of layer of compressive stress (DOL) greater than about 10 microns. In further embodiments, the first, second and/or third glass substrate may have a compressive stress greater than about 500 MPa and a DOL greater than about 20 microns, or a compressive stress greater than about 700 MPa and a DOL greater than about 40 microns. In non-limiting embodiments, the first, second and/or third glass substrate can have a thickness of less than or equal to about 3 mm, for example, ranging from about 0.1 mm to about 2.5 mm, from about 0.3 mm to about 2 mm, from about 0.5 mm to about 1.5 mm, or from about 0.7 mm to about 1 mm, including all ranges and subranges therebetween.

The first, second and/or third glass substrates can, in various embodiments, be transparent or substantially transparent. As used herein, the term “transparent” is intended to denote that the substrate, at a thickness of approximately 1 mm, has a transmission of greater than about 80% in the visible region of the spectrum (400-700 nm). For instance, an exemplary transparent substrate may have greater than about 85% transmittance in the visible light range, such as greater than about 90%, or greater than about 95%, including all ranges and subranges therebetween. In certain embodiments, an exemplary glass substrate may have a transmittance of greater than about 50% in the ultraviolet (UV) region (200-400 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween. In non-limiting embodiments, the lens 100 may also be transparent or substantially transparent as set forth above.

According to various embodiments, the second substrate 207 can be chosen from inorganic substrates, such as inorganic substrates having a thermal conductivity greater than that of glass. For example, suitable inorganic substrates may include those with a relatively high thermal conductivity, such as greater than about 2.5 W/m-K (e.g., greater than about 2.6, 3, 5, 7.5, 10, 15, 20, 25, 30, 40, 50, 60, 70, 80, 90, or 100 W/m-K), for instance, ranging from about 2.5 W/m-K to about 100 W/m-K, including all ranges and subranges therebetween. In some embodiments, the thermal conductivity of the inorganic substrate can be greater than 100 W/m-K, such as ranging from about 100 W/m-K to about 300 W/m-K (e.g., greater than about 100, 110, 120, 130, 140, 150, 160, 170, 180, 190, 200, 210, 220, 230, 240, 250, 260, 270, 280, 290, or 300 W/m-K), including all ranges and subranges therebetween.

According to various embodiments, the inorganic substrate can comprise a ceramic substrate, which can include ceramic or glass-ceramic substrates. In a non-limiting embodiment, the second substrate 207 can comprise aluminum nitride, aluminum oxide, beryllium oxide, boron nitride, or silicon carbide, to name a few. The thickness of the inorganic substrate can range, in certain embodiments, from about 0.1 mm to about 3 mm, such as from about 0.2 mm to about 2.5 mm, from about 0.3 mm to about 2 mm, from about 0.4 mm to about 1.5 mm, from about 0.5 mm to about 1 mm, from about 0.6 mm to about 0.9 mm, or from about 0.7 mm to about 0.8 mm, including all ranges and subranges therebetween.

While FIGS. 5A-C depict the at least one cavity 209 as having a trapezoidal cross-section, it is to be understood that the cavities can have any given shape or size, as desired for a given application. For example, the cavities can have a square, cylindrical, rectangular, semi-circular, or semi-elliptical cross-section, or an irregular cross-section, to name a few. It is also possible for the surface of the first substrate 201 or third substrate 215 to comprise at least one cavity 209 (see, e.g., FIG. 5C), or for both the first or third and second substrates to comprise cavities. Alternatively, or additionally, cavities in the first or second substrates can be filled with a material that is transparent at one or both of visible wavelengths or LED operating wavelengths.

Moreover, while FIGS. 5A-D depict a sealed device comprising a single cavity 209, sealed devices comprising a plurality or array of cavities are also intended to fall within the scope of the disclosure. For example, the sealed device can comprise any number of cavities 209, which can be arranged and/or spaced apart in any desired fashion including regular and irregular patterns. Furthermore, while the single cavity 209 in FIGS. 5A-B comprises both quantum dots and an LED component, it is to be understood that this depiction is not limiting. Embodiments in which one or more cavities do not comprise quantum dots and/or LED components are also envisioned (see, e.g., FIG. 5C). Embodiments in which one or more cavities comprise a plurality of LED components and/or quantum dots are also envisioned. Moreover, it is not required that each cavity comprise the same number or amount of quantum dots and/or LED components, it being possible for this amount to vary from cavity to cavity and for some cavities to comprise no quantum dots and/or LED components. Furthermore, while FIGS. 5A-D each depict a lens comprising a single negative axicon optically coupled to the sealed device, it is to be understood that lenses comprising multiple negative axicons can also be coupled to such sealed devices, or any other encapsulated or non-encapsulated light emitting device, without limitation.

The at least one cavity 209 can have any given depth, which can be chosen as appropriate, e.g., for the type and/or shape and/or amount of the item (e.g., QD, LED, and/or LD) to be encapsulated in the cavity. By way of non-limiting embodiment, the at least one cavity 209 can extend into the first and/or second substrates to a depth of less than about 1 mm, such as less than about 0.5 mm, less than about 0.4 mm, less than about 0.3 mm, less than about 0.2 mm, less than about 0.1 mm, less than about 0.05 mm, less than about 0.02 mm, or less than about 0.01 mm, including all ranges and subranges therebetween, such as ranging from about 0.01 mm to about 1 mm. It is also envisioned that an array of cavities can be used, each cavity having the same or a different depths, the same or a different shapes, and/or the same or a different sizes, as compared to the other cavities in the array.

The at least one cavity 209 can, in some embodiments, comprise at least one quantum dot 205. Quantum dots can have varying shapes and/or sizes depending on the desired wavelength of emitted light. For example, the frequency of emitted light may increase as the size of the quantum dot decreases, e.g., the color of the emitted light can shift from red to blue as the size of the quantum dot decreases. When irradiated with blue, UV, or near-UV light, a quantum dot may convert the light into longer red, yellow, green, or blue wavelengths. According to various embodiments, the quantum dot can be chosen from red and green quantum dots, emitting in the red and green wavelengths when irradiated with blue, UV, or near-UV light. For instance, the LED component can emit blue light (approximately 450-490 nm), UV light (approximately 200-400 nm), or near-UV light (approximately 300-450 nm).

Additionally, it is possible that the at least one cavity can comprise the same or different types of quantum dots, e.g., quantum dots emitting different wavelengths. For example, in some embodiments, a cavity can comprise quantum dots emitting both green and red wavelengths, to produce a red-green-blue (RGB) spectrum in the cavity. However, according to other embodiments, it is possible for an individual cavity to comprise only quantum dots emitting the same wavelength, such as a cavity comprising only green quantum dots or a cavity comprising only red quantum dots. For instance, the sealed device can comprise an array of cavities, in which approximately one-third of the cavities may be filled with green quantum dots and approximately one-third of the cavities may be filled with red quantum dots, while approximately one-third of the cavities may remain empty (so as to emit blue light). Using such a configuration, the entire array can produce the RGB spectrum, while also providing dynamic dimming for each individual color.

Of course it is to be understood that cavities containing any type, color, or amount of quantum dots in any ratio are possible and envisioned as falling within the scope of the disclosure. It is within the ability of one skilled in the art to choose the configuration of the cavity or cavities and the types and amounts of quantum dots to place in each cavity to achieve a desired effect. Moreover, although the devices herein are discussed in terms of red and green quantum dots for display devices, it is to be understood that any type of quantum dot can be used, which can emit any wavelength of light including, but not limited to, red, orange, yellow, green, blue, or any other color in the visible spectrum (e.g., 400-700 nm).

Exemplary quantum dots can have various shapes. Examples of the shape of a quantum dot include, but are not limited to, sphere, rod, disk, tetrapod, other shapes, and/or mixtures thereof. Exemplary quantum dots may also be contained in a polymer resin such as, but not limited to, acrylate or another suitable polymer or monomer. Such exemplary resins may also include suitable scattering particles including, but not limited to, TiO₂ or the like.

In certain embodiments, quantum dots comprise inorganic semiconductor material which permits the combination of the soluble nature and processability of polymers with the high efficiency and stability of inorganic semiconductors. Inorganic semiconductor quantum dots are typically more stable in the presence of water vapor and oxygen than their organic semiconductor counterparts. As discussed above, because of their quantum-confined emissive properties, their luminescence can be extremely narrow-band and can yield highly saturated color emission, characterized by a single Gaussian spectrum. Because the nanocrystal diameter controls the quantum dot optical band gap, the fine tuning of absorption and emission wavelength can be achieved through synthesis and structure change.

In certain embodiments, inorganic semiconductor nanocrystal quantum dots comprise Group IV elements, Group II-VI compounds, Group II-V compounds, Group III-VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

In certain embodiments a quantum dot can include a shell over at least a portion of a surface of the quantum dot. This structure is referred to as a core-shell structure. The shell can comprise an inorganic material, more preferably an inorganic semiconductor material. An inorganic shell can passivate surface electronic states to a far greater extent than organic capping groups. Examples of inorganic semiconductor materials for use in a shell include, but are not limited to, Group IV elements, Group II-VI compounds, Group II-V compounds, Group III-VI compounds, Group III-V compounds, Group IV-VI compounds, Group I-III-VI compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

In some embodiments, quantum dot materials can include II-VI semiconductors, including CdSe, CdS, and CdTe, and can be made to emit across the entire visible spectrum with narrow size distributions and high emission quantum efficiencies. For example, roughly 2 nm diameter CdSe quantum dots emit in the blue while 8 nm diameter particles emit in the red. Changing the quantum dot composition by substituting other semiconductor materials with a different band gap into the synthesis alters the region of the electromagnetic spectrum in which the quantum dot emission can be tuned. In other embodiments, the quantum dot materials are cadmium-free. Examples of cadmium-free quantum dot materials include InP and InₓGaₓ₋₁P. In an example of one approach for preparing InₓGaₓ₋₁P, InP can be doped with a small amount of Ga to shift the band gap to higher energies in order to access wavelengths slightly bluer than yellow/green. In an example of another approach for preparing this ternary material, GaP can be doped with In to access wavelengths redder than deep blue. InP has a direct bulk band gap of 1.27 eV, which can be tuned beyond 2 eV with Ga doping. Quantum dot materials comprising InP alone can provide tunable emission from yellow/green to deep red; the addition of a small amount of Ga to InP can facilitate tuning the emission down into the deep green/aqua green. Quantum dot materials comprising InₓGaₓ₋₁P (0<x<1) can provide light emission that is tunable over at least a large portion of, if not the entire, visible spectrum. InP/ZnSeS core-shell quantum dots can be tuned from deep red to yellow with efficiencies as high as 70%. For creation of high CRI white QD-LED emitters, InP/ZnSeS can be utilized to address the red to yellow/green portion of the visible spectrum and InₓGaₓ₋₁P will provide deep green to aqua-green emission.

In some embodiments, e.g., see FIGS. 5A-D, the quantum dot materials can provide a tunable emission in a predetermined spectrum. For example, exemplary quantum dot materials may be selected such that emission therefrom is only in single spectrum, i.e., single wavelength quantum dot material, such as but not limited to the red spectrum, e.g., from about 620 nm to about 750 nm. Of course, exemplary single wavelength quantum dot materials may be selected such that other spectrum (e.g., violet 308-450 nm, blue 450-495 nm, green 495-570 nm, yellow 570-590 nm, and orange 590-620 nm) are emitted when excited by a nearby light source such as the at least one LED component 203. In other embodiments, the quantum dot materials can provide a tunable emission in another spectrum such as but not limited to the infrared spectrum, e.g., from 700 nm to 1 mm, or the ultraviolet spectrum, e.g., from 10 nm to 380 nm.

A first surface of the first substrate 201 and a second surface of the second substrate 207 can be joined by a seal or weld 211. The seal 211 can extend around the at least one cavity 209, thereby sealing the workpiece within the cavity. For example, as shown in FIGS. 5A-B the seal can encapsulate the at least one quantum dot 205 and the at least one LED component 203 in the same cavity. In the case of multiple cavities, the seal can extend around a single cavity, e.g., separating each cavity from the other cavities in the array to create one or more discrete sealed regions or pockets, or the seal can extend around more than one cavity, e.g., a group of two or more cavities, such as three, four, five, ten, or more cavities and so forth. It is also possible for the sealed device to comprise one or more cavities that may not be sealed, as desired, for example, in the case of a cavity devoid of an LED and/or quantum dots. Thus, it is to be understood that various cavities can be empty or otherwise free of quantum dots and/or LEDs, these empty cavities thus being sealed or unsealed as appropriate or desired. In some embodiments, the seal 211 can comprise a glass-to-glass seal, a glass-to-glass-ceramic seal, or a glass-to-ceramic seal as described in co-pending U.S. application Ser. Nos. 13/777,584; 13/891,291; 14/270,828; and Ser. No. 14/271,797, all of which are incorporated herein by reference in their entireties.

The first and second substrates can, in various embodiments be sealed together as disclosed herein, to produce a seal or weld around the at least one cavity. In certain embodiments, the seal or weld may be a hermetic seal, e.g., forming one or more air-tight and/or waterproof pockets in the device. For example, at least one cavity can be hermetically sealed such that the cavity is impervious or substantially impervious to water, moisture, air, and/or other contaminants. By way of non-limiting example, a hermetic seal can be configured to limit the transpiration (diffusion) of oxygen to less than about 10⁻² cm³/m²/day (e.g., less than about 10⁻³/cm³/m²/day), and limit transpiration of water to about 10⁻² g/m²/day (e.g., less than about 10⁻³, 10⁻⁴, 10⁻⁵, or 10⁻⁶ g/m²/day). In various embodiments, a hermetic seal can substantially prevent water, moisture, and/or air from contacting the components protected by the hermetic seal.

According to certain aspects, the total thickness of the sealed device can be less than about 6 mm, such as less than about 5 mm, less than about 4 mm, less than about 3 mm, less than about 2 mm, less than about 1.5 mm, less than about 1 mm, or less than about 0.5 mm, including all ranges and subranges therebetween. For example, the thickness of the sealed device can range from about 0.3 mm to about 3 mm, such as from about 0.5 mm to about 2.5 mm, or from about 1 mm to about 2 mm, including all ranges and subranges therebetween.

The optical assemblies disclosed herein may be used in various display devices or display components including, but not limited to backlights or backlit displays such as televisions, computer monitors, handheld devices, and the like, which can comprise various additional components. The optical assemblies disclosed herein can also be used in illuminating devices, such as luminaires and solid state lighting applications. For example, the optical assemblies can be used for general illumination, e.g. mimicking the broadband output of the sun. Such lighting devices can comprise, for example, quantum dots of various sizes emitting at various wavelengths, such as wavelengths ranging from 400-700 nm.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “an axicon” includes examples having one such “axicon” or two or more such “axicons” unless the context clearly indicates otherwise. Similarly, a “plurality” or an “array” is intended to denote two or more, such that an “array of axicons” or a “plurality of axicons” denotes two or more such axicons.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

All numerical values expressed herein are to be interpreted as including “about,” whether or not so stated, unless expressly indicated otherwise. It is further understood, however, that each numerical value recited is precisely contemplated as well, regardless of whether it is expressed as “about” that value. Thus, “a dimension less than 10 mm” and “a dimension less than about 10 mm” both include embodiments of “a dimension less than about 10 mm” as well as “a dimension less than 10 mm.”

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a device comprising A+B+C include embodiments where a device consists of A+B+C, and embodiments where a device consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

1. A lens comprising a first surface, a second convex surface, and a central region disposed therebetween, wherein the central region comprises at least one negative axicon.

2. The lens of claim 1, wherein the at least one negative axicon is configured to direct a portion of light passing through the lens towards the second convex surface at angles of incidence sufficient for total internal reflection to occur within the lens.

3. The lens of claim 1, wherein the first surface is chosen from planar, rotationally symmetric spherical, rotationally symmetric aspherical, and rotationally asymmetric free form surfaces.

4. The lens of claim 1, wherein the second convex surface is chosen from rotationally symmetric spherical, rotationally symmetric aspherical, and rotationally asymmetric free form surfaces.

5. The lens of claim 1, wherein the first surface is planar and the second convex surface is a rotationally symmetrical spherical surface.

6. The lens of claim 1, wherein the second convex surface comprises a conical depression having a cone half-angle ranging from about 80° to about 90°.

7. The lens of claim 1, wherein the at least one negative axicon comprises a hollow conical region having a cone half-angle ranging from about 25° to about 40°.

8. The lens of claim 1, wherein the central region comprises a plurality of negative axicons.

9. The lens of claim 1, wherein a thickness extending between the first surface and an apex of the second convex surface ranges from about 1 mm to about 20 mm.

10. The lens of claim 1, comprising a material chosen from glass and poly(methyl methacrylate).

11. An optical assembly comprising at least one lens according to claim 1 optically coupled to at least one light emitting device.

12. The optical assembly of claim 11, wherein the at least one light emitting device is a light emitting diode.

13. The optical assembly of claim 11, wherein the at least one lens is spaced apart from the at least one light emitting device by a distance ranging from about 0.1 mm to about 5 mm.

14. The optical assembly of claim 11, further comprising a light diffusing layer and at least one color converting element, wherein the at least one color converting element is a quantum dot.

15. (canceled)

16. (canceled)

17. The optical assembly of claim 11, wherein the at least one lens is optically coupled to a sealed device comprising at least one cavity containing at least one quantum dot and at least one light emitting diode.

18. The optical assembly of claim 17, wherein the sealed device comprises a first substrate and a second substrate bonded together by a sealing layer.

19. The optical assembly of claim 18, wherein the sealed device further comprises one or more films to filter predetermined wavelengths of light.

20. The optical assembly of claim 19, wherein the one or more films comprises alternating films of high refractive index material and low refractive index material.

21. The optical assembly of claim 20, wherein the high refractive index material is selected from the group consisting of Nb₂O₅, Ta₂O₅, TiO₂, and compound oxides thereof, and wherein the low refractive index material is selected from the group consisting of SiO₂, ZrO₂, HfO₂, Bi₂O₃, La₂O₃, Al₂O₃, and compound oxides thereof.

22. A display device comprising the optical assembly according to claim 11.

23. A luminaire comprising the optical assembly according to claim 11.
